(19) United States
(12) Patent Application Publication
(10) Pub. No.: US 2025/0133655 A1
(43) Pub. Date: Apr. 24, 2025

(54) CIRCUIT BOARD STRUCTURE

(71) Applicant: Tripod (WUXI) Electronic Co., Ltd., WuXi City (CN)

(72) Inventors: CHI SUN, WuXi City (CN); HAI YANG, WuXi City (CN); HUA-RONG GUI, WuXi City (CN)

(21) Appl. No.: 18/924,057

(22) Filed: Oct. 23, 2024

(30) Foreign Application Priority Data
Oct. 24, 2023 (CN) 202322864291.6

(51) Int. Cl. H05K 1/02

(52) U.S. Cl. CPC H05K 1/0298; H05K 2201/09036; H05K 2201/09536

(57) ABSTRACT

A circuit board structure is provided. The circuit board structure includes a core substrate, two inner substrates, at least one groove structure, at least one thru-hole, and a plating layer. The core substrate includes two side surfaces opposite two each other. The two inner substrates are laminated on the two side surfaces of the core substrate. The at least one groove structure is formed between the core substrate and one of the inner substrates. The at least one groove structure includes two lateral grooves facing toward each other. The at least one thru-hole penetrates through the two inner substrates and the core substrate. The two lateral grooves of the at least one groove structure are arranged at two sides of the at least one thru-hole. The plating layer is formed on an inner side wall of the thru-hole. The plating layer has a plurality of plating gaps.

### CROSS-REFERENCE TO RELATED PATENT APPLICATION

This application claims the benefit of priority to China Patent Application No. 202322864291.6, filed on Oct. 24, 2023, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board structure, and more particularly to a circuit board structure that has lateral grooves.

### BACKGROUND OF THE DISCLOSURE

A back drilling depth of a conventional circuit board cannot be easily controlled, such that a back drilling depth tolerance of the circuit board is excessive.

Therefore, how to improve the circuit board to overcome the above-mentioned defects has become one of the most important issues in this field.

### SUMMARY OF THE DISCLOSURE

In response to the above-referenced technical inadequacy, the present disclosure provides a circuit board structure to effectively reduce an excessive back drilling depth tolerance of a conventional circuit board.

In order to solve the above-mentioned problems, one of the technical aspects adopted by the present disclosure is to provide a circuit board structure. The circuit board structure includes a core substrate, two inner substrates, at least one groove structure, at least one thru-hole, and a plating layer. The core substrate has two side surfaces opposite to each other. The two inner substrates are laminated on the two side surfaces of the core substrate. The at least one groove structure is formed between the core substrate and one of the two inner substrates. The at least one groove structure includes two lateral grooves facing toward each other. The at least one thru-hole penetrates through the two inner substrates and the core substrate. The two lateral grooves of the at least one groove structure are arranged at two sides of the at least one thru-hole. The plating layer is formed on an inner wall of the at least one thru-hole. The plating layer has a plurality of plating gaps.

In one of the possible or preferred embodiments, in the at least one groove structure, a distance between the two lateral grooves is between 125 μm and 400 μm.

In one of the possible or preferred embodiments, in the at least one groove structure, a depth of each of the lateral grooves along a horizontal direction is between 4 mil and 8 mil.

In one of the possible or preferred embodiments, a distance of each of the plating gaps along a vertical direction is between 20 μm and 80 μm.

In one of the possible or preferred embodiments, the plating layer is not formed on positions of the inner side wall of the at least one thru-hole corresponding to the two lateral grooves.

In one of the possible or preferred embodiments, two groove structures are respectively formed between the core substrate and the two inner substrates, the two groove structures are respectively arranged at the two side surfaces of the core substrate, and each of the groove structures includes two lateral grooves facing toward each other.

In one of the possible or preferred embodiments, a quantity of the thru-hole is two, and each of the thru-holes is arranged between the two lateral grooves of corresponding one of the groove structures.

In one of the possible or preferred embodiments, in the at least one groove structure, the two lateral grooves are formed by removing an ink layer in the two lateral grooves, and ink remains in each of the lateral grooves.

In one of the possible or preferred embodiments, the ink undergoes no qualitative change in an environment having a temperature of between 75° C. and 95° C. and a sodium hydroxide concentration of between 35 g/L and 55 g/L.

In one of the possible or preferred embodiments, the ink undergoes no qualitative change in an environment having a temperature of between 20° C. and 40° C. and a sulfuric acid concentration of between 10 ml/L and 30 ml/L.

Therefore, in the circuit board provided by the present disclosure, by virtue of “the circuit board structure including at least one groove structure” and “the at least one groove structure including two lateral grooves facing toward each other,” the excessive back drilling depth tolerance of the conventional circuit board can be effectively reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for producing a circuit board according to an embodiment of the present disclosure;

FIG. 2 is a schematic view of an ink layer forming process of the method for producing the circuit board according to the embodiment of the present disclosure;

FIG. 3 is a schematic view of a laminating process of the method for producing the circuit board according to the embodiment of the present disclosure;

FIG. 4 is a schematic view of a thru-hole forming process of the method for producing the circuit board according to the embodiment of the present disclosure;

FIG. 5 is a schematic view of an activating process of the method for producing the circuit board according to the embodiment of the present disclosure;

FIG. 6 is a schematic view of an ink removing process of the method for producing the circuit board according to the embodiment of the present disclosure; and

FIG. 7 is a schematic view of the circuit board structure according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [Method for Producing a Circuit Board Structure]

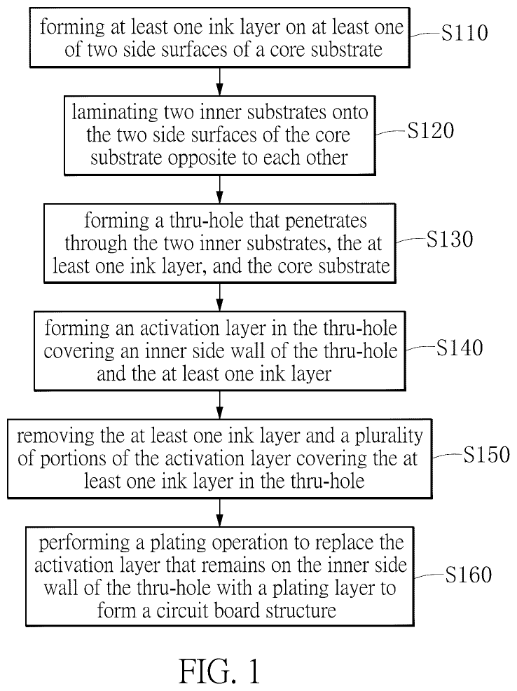

Referring to FIG. 1, FIG. 1 is a flowchart of a method for producing a circuit board according to an embodiment of the present disclosure. An embodiment of the present disclosure provides a method for producing a circuit board structure. The method for producing the circuit board structure includes an ink layer forming process S110, a laminating process S120, a thru-hole forming process S130, an activating process S140, an ink removing process S150, and a plating process S160. Naturally, the method for producing the circuit board structure can include other processes (e.g., a browning process, a glue removing process, a solder mask process, or a back drilling process) according to practical requirements, but they are not the key techniques to be protected by the present disclosure, and will not be reiterated herein.

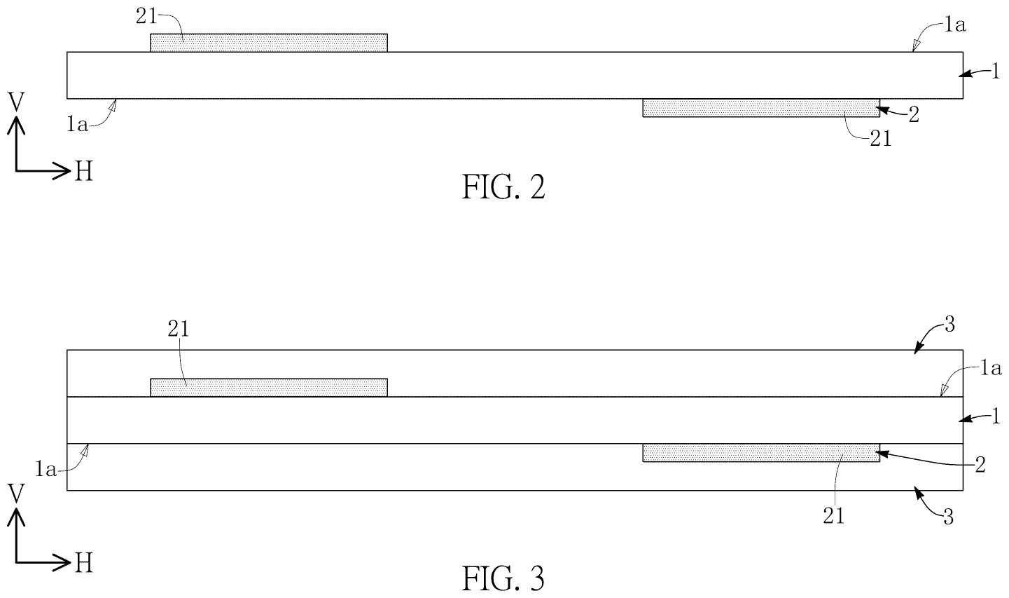

Referring to FIG. 2, FIG. 2 is a schematic view of an ink layer forming process of the method for producing the circuit board according to the embodiment of the present disclosure. In the ink layer forming process S110, an ink layer 2 is formed on one of two side surfaces 1a of a core substrate 1. It is worth mentioning that, an ink 21 forming the ink layer 2 can have an acid, alkali, and high temperature resistance. For example, the ink 21 forming the ink layer 2 undergoes no qualitative change in an environment having a temperature of between 75° C. and 95° C. and a sodium hydroxide concentration of between 35 g/L and 55 g/L, and the ink 21 forming the ink layer 2 undergoes no qualitative change in an environment having a temperature of between 20° C. and 40° C. and a sulfuric acid concentration of between 10 ml/L and 30 ml/L.

Preferably, the ink 21 forming the ink layer 2 undergoes no qualitative change in an environment having a temperature of between 80° C. and 90° C. (more preferably, about 85° C.) and a sodium hydroxide concentration of between 40 g/L and 50 g/L (more preferably, about 45 g/L), and the ink 21 forming the ink layer 2 undergoes no qualitative change in an environment having a temperature of between 25° C. and 35° C. (more preferably, about 30° C.) and a sulfuric acid concentration of between 15 ml/L and 25 ml/L (more preferably, about 20 ml/L). The above-mentioned qualitative change can be each type of property change. In addition, the ink 21 undergoes no qualitative change at a relatively low or relatively high pH value (e.g., a pH value of lower than 4 or higher than 10).

Since the ink layer 2 will undergo relevant circuit board procedures, if the ink 21 forming the ink layer 2 does not have enough acid, alkali, and high temperature resistance, the property of the finally-formed circuit board might be affected. In addition, as long as the ink layer 2 can meet the above-mentioned environment condition and can be applied to circuit board procedure, the present disclosure does not limit the specific material of the ink 21 forming the ink layer 2.

Referring to FIG. 3, FIG. 3 is a schematic view of a laminating process of the method for producing the circuit board according to the embodiment of the present disclosure. In the laminating process S120, two inner substrates 3 are laminated onto the two side surfaces 1a of the core substrate 1 opposite to each other, such that the core substrate 1 is sandwiched between the two inner substrates 3.

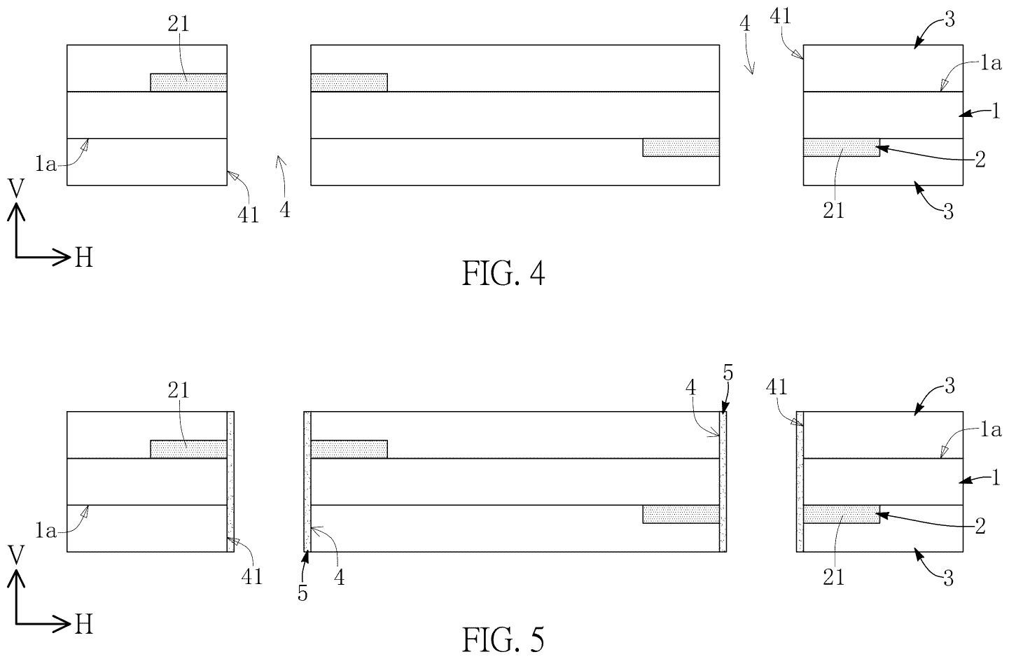

Referring to FIG. 4, FIG. 4 is a schematic view of a thru-hole forming process of the method for producing the circuit board according to the embodiment of the present disclosure. In the thru-hole forming process S130, a thru-hole 4 penetrating through the two inner substrates 3, the ink layer 2, and the core substrate 1 is formed. The thru-hole 4 can be formed, for example, in a mechanical drilling manner or in a laser drilling manner, but the present disclosure does not limit the manner in which the thru-hole 4 is formed.

Referring to FIG. 5, FIG. 5 is a schematic view of an activating process of the method for producing the circuit board according to the embodiment of the present disclosure. In the activating process S140, an activation layer 5 covering an inner side wall 41 of the thru-hole 4 and the ink layer 2 is formed. Specifically, in the activation process S140, the activation layer 5 formed on the inner side 41 wall of the thru-hole 4 includes palladium ions, so as to facilitate the subsequent plating process S160 for plating in the thru-hole 4.

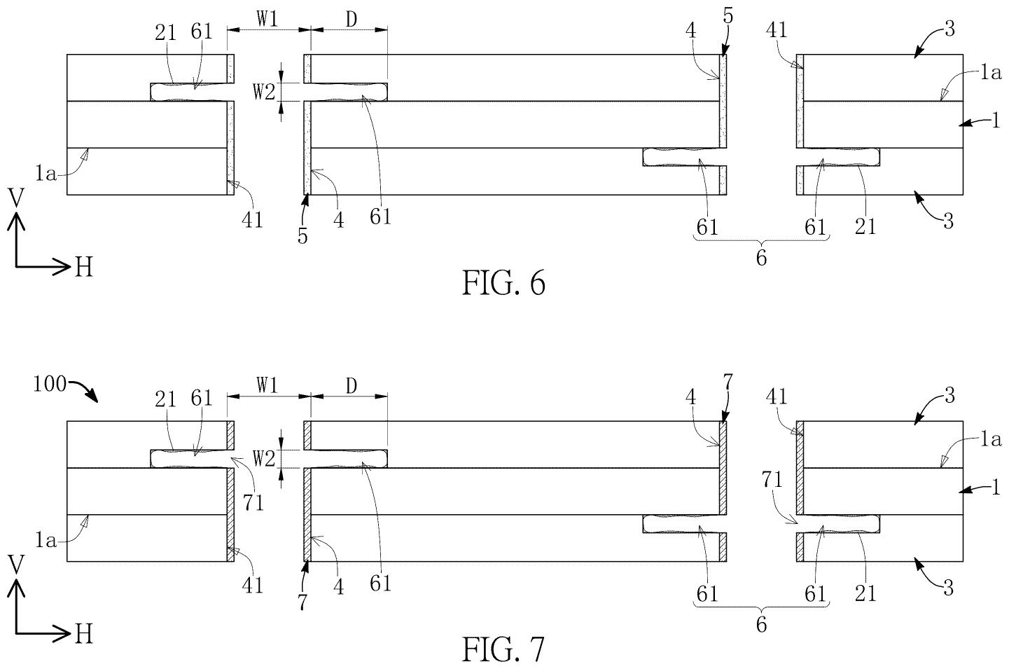

Referring to FIG. 6, FIG. 6 is a schematic view of an ink removing process of the method for producing the circuit board according to the embodiment of the present disclosure. In the ink removing process S150, the ink layer 2 and a plurality of portions of the activation layer 5 covering the ink layer 2 in the thru-hole 4 are removed. In the ink removing process S150, the ink layer 2 and the portions of the activation layer 5 covering the ink layer 2 in the thru-hole 4 can be removed in a washing manner, but the present disclosure does not limit the manner in which the ink layer 2 and the portions of the activation layer 5 are removed.

After the ink removing process S150, a groove structure 6 is formed between the core substrate 1 and one of the two inner substrates 3, and the groove structure 6 includes two lateral grooves 61 facing toward each other. In the groove structure 6, a distance W1 between the two lateral grooves 61 is between 125 μm and 400 μm, and a depth D of each of the lateral grooves 61 along a horizontal direction H is between 4 mil and 8 mil. It is worth mentioning that, the distance W1 between the two lateral grooves 61 can be regarded as a shortest distance between an opening of one of the lateral grooves 61 and an opening of another one of the lateral grooves 61. In addition, the groove structure 6 can be regarded as an undrillable structure in the back drilling process, so as to achieve an effect of back drilling depth tolerance approaching 0 mil or equal to 0 mil.

Referring to FIG. 7, FIG. 7 is a schematic view of the circuit board structure according to the embodiment of the present disclosure. In the plating process S160, a plating operation is performed to replace the activation layer 5 that remains on the inner side wall 41 of the thru-hole 4 with a plating layer 7 to form a circuit board structure 100.

After the plating process S160, the plating layer 7 is not formed on positions of the inner side wall 41 of the thru-hole 4 corresponding to the two lateral grooves 61. It is worth mentioning that, the plating process S160 of the present disclosure can be regarded as plating on positions where the activation layer 5 is formed in the thru-hole 4. After the ink removing process S150, activation layer 5 is partially removed at the positions corresponding to the lateral grooves 61, and accordingly, in the plating process S160, the plating layer 7 is not formed on the positions in the thru-hole 4 corresponding to the lateral grooves 61. In other words, in a sectional view of the circuit board structure 100, the plating layer 7 is in a discontinuous shape.

After the plating process S160, a plurality of plating gaps 71 are formed on the inner side wall 41 of the thru-hole 4, and a distance W2 of each of the plating gap 71 along a vertical direction V is between 20 μm and 80 μm. The position and the quantity of the plating gaps 71 correspond to those of the lateral grooves 61. Specifically, the plating gaps 71 are formed since the activation layer 5 on the inner side wall 41 of the thru-hole 4 is partially removed.

The quantity of the groove structure 6 can correspond to the quantity of the thru-hole 4, and both the quantity of the groove structure 6 and the quantity of the thru-hole 4 can be changed according to practical requirements. In the ink layer forming process S110, two ink layers 2 can be respectively formed on the two side surfaces 1a of the core substrate 1. In the thru-hole forming process S130, two thru-holes 4 can be formed, and each of the thru-holes 4 penetrates through the two inner substrates 3, one of the ink layers 2, and the core substrate 1.

After the ink removing process S150, two groove structures 6 are respectively formed between the core substrate 1 and the two inner substrates 3, the two groove structures 6 are respectively arranged at the two side surfaces 1a of the core substrate 1, and each of the groove structures 6 includes two lateral grooves 61 facing toward each other.

### [Circuit Board Structure]

Referring to FIG. 7, the present disclosure provides a circuit board structure 100, the circuit board structure 100 can be produced by implementing the above-mentioned method for producing the circuit board structure, but the present disclosure is not limited thereto. The circuit board structure 100 includes a core substrate 1, two inn substrates 3, at least on groove structure 6, at least one thru-hole 4, and a plating layer 7.

The core substrate 1 includes two side surfaces 1a opposite to each other, the two inner substrates 3 are laminated on the two side surfaces 1a of the core substrate 1, such that the core substrate 1 is sandwiched between the two inner substrates 3.

The at least one groove structure 6 is formed between the core substrate 1 and one of the inner substrates 3. The groove structure 6 includes two lateral grooves 61 facing toward each other.

In the groove structure 6, a distance W1 between the two lateral grooves 61 is between 125 μm and 400 μm, and a depth D of each of the lateral grooves 61 along a horizontal direction H is between 4 mil and 8 mil.

In the groove structure 6, the two lateral grooves 61 are formed by removing ink layers 2 therein, and each of the lateral grooves 61 has ink 21 that remains therein. The ink 21 undergoes no qualitative change in an environment having a temperature of between 75° C. and 95° C. and a sodium hydroxide concentration of between 35 g/L and 55 g/L, and the ink 21 undergoes no qualitative change in an environment having a temperature of between 20° C. and 40° C. and a sulfuric acid concentration of between 10 ml/L and 30 ml/L.

The at least one thru-hole 4 penetrates through the two inner substrates 3 and the core substrate 1. The two lateral grooves 61 of the groove structure 6 are arranged at two sides of the thru-hole 4.

The plating layer 7 is formed on an inner side wall 41 of the thru-hole 4. The plating layer 7 has a plurality of plating gaps 71, and the quantity of the plating gaps 71 corresponds to the quantity of the lateral grooves 61. A distance W2 of each of the plating gaps 71 along a vertical direction V is between 20 μm and 80 μm. In addition, the inner side wall 41 of the thru-hole 4 does not have the plating layer 7 formed on positions corresponding to the two lateral grooves 61.

The quantity of the groove structure 6 can correspond to the quantity of the thru-hole 4, and both the quantity of the groove structure 6 and the quantity of the thru-hole 4 can be changed according to practical requirements. For example, two groove structures 6 can be respectively formed between the core substrate 1 and the two inner substrates 3, the two groove structures 6 are respectively arranged at the two side surfaces 1a of the core substrate 1, and each of the groove structures 6 includes two lateral grooves 61 facing toward each other. The quantity of the thru-hole 4 can be two, and each of the thru-holes 4 is arranged between two lateral grooves 61 of one of the groove structures 6.

### Beneficial Effects of the Embodiment

In conclusion, in the circuit board provided by the present disclosure, by virtue of “the circuit board structure including at least one groove structure” and “the at least one groove structure including two lateral grooves facing toward each other,” the excessive back drilling depth tolerance of the conventional circuit board can be effectively reduced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit board structure, comprising:
a core substrate having two side surfaces opposite to each other;
two inner substrates laminated on the two side surfaces of the core substrate;
at least one groove structure formed between the core substrate and one of the two inner substrates, wherein the at least one groove structure includes two lateral grooves facing toward each other;
at least one thru-hole penetrating through the two inner substrates and the core substrate, wherein the two lateral grooves of the at least one groove structure are arranged at two sides of the at least one thru-hole; and
a plating layer formed on an inner wall of the at least one thru-hole, wherein the plating layer has a plurality of plating gaps.

2. The circuit board structure according to claim 1, wherein, in the at least one groove structure, a distance between the two lateral grooves is between 125 μm and 400 μm.

3. The circuit board structure according to claim 1, wherein, in the at least one groove structure, a depth of each of the lateral grooves along a horizontal direction is between 4 mil and 8 mil.

4. The circuit board structure according to claim 1, wherein a distance of each of the plating gaps along a vertical direction is between 20 μm and 80 μm.

5. The circuit board structure according to claim 1, wherein the plating layer is not formed on positions of the inner side wall of the at least one thru-hole corresponding to the two lateral grooves.

6. The circuit board structure according to claim 1, wherein two groove structures are respectively formed between the core substrate and the two inner substrates, the two groove structures are respectively arranged at the two side surfaces of the core substrate, and each of the groove structures includes two lateral grooves facing toward each other.

7. The circuit board structure according to claim 6, wherein a quantity of the thru-hole is two, and each of the thru-holes is arranged between the two lateral grooves of corresponding one of the groove structures.

8. The circuit board structure according to claim 1, wherein, in the at least one groove structure, the two lateral grooves are formed by removing an ink layer in the two lateral grooves, and ink remains in each of the lateral grooves.

9. The circuit board structure according to claim 8, wherein the ink undergoes no qualitative change in an environment having a temperature of between 75° C. and 95° C. and a sodium hydroxide concentration of between 35 g/L and 55 g/L.

10. The circuit board structure according to claim 8, wherein the ink undergoes no qualitative change in an environment having a temperature of between 20° C. and 40° C. and a sulfuric acid concentration of between 10 ml/L and 30 ml/L.
